(19) United States
(12) Patent Application Publication
(10) Pub. No.: US 2016/0078964 A1
(43) Pub. Date: Mar. 17, 2016

(54) METHOD FOR TESTING REDUNDANCY AREA IN SEMICONDUCTOR MEMORY DEVICE

(71) Applicant: SAMSUNG ELECTRONICS CO., LTD., Suwon-si (KR)

(72) Inventor: Bum-Jun KWON, Incheon (KR)

(21) Appl. No.: 14/736,404

(22) Filed: Jun. 11, 2015

(30) Foreign Application Priority Data
Sep. 12, 2014 (KR) 10-2014-0121180

(51) Int. Cl. G11C 29/02; G11C 29/00

(52) U.S. Cl. CPC G11C 29/027; G11C 29/78

(57) ABSTRACT

A method tests a redundancy area of a semiconductor memory device. The method includes receiving a redundancy address to select a redundancy area including spare memory cells to repair normal memory cells, checking the redundancy address based on repair use information to determine whether the redundancy area is an actually repaired area, enabling the redundancy area when the redundancy area is the actually repaired area, and outputting data read from the enabled redundancy area to practically perform a redundancy area test.

### CROSS-REFERENCE TO RELATED APPLICATION

Korean Patent Application No. 10-2014-0121180, filed on Sep. 12, 2014, and entitled, “Method for Testing Redundancy Area in Semiconductor Memory Device,” is incorporated by reference herein in its entirety.

### BACKGROUND

1. Field

One or more embodiments described herein relate to a method for testing a redundancy area in a semiconductor memory device.

2. Description of the Related Art

A data processing system may use a memory module as a working memory. The memory module may include a plurality of dynamic random access memories (DRAMs) controlled by a memory controller. The memory controller receives requests from a processor to perform various memory control operations.

Each DRAM includes a plurality of memory cells, and each cell includes an access transistor and a storage capacitor. When it is difficult to properly retain data in a memory cell, the memory cell may be considered to be defective.

Various attempts have been made to repair a defective memory cell. One attempt involves using a spare memory cell in a redundancy area. For example, a cell-to-cell, row-to-row, column-to-column, or block-to-block repair unit may be used in an attempt to repair one or more defective memory cells.

The redundancy area is at an edge portion of a main array area. Thus, a bridge defect may occur between the redundancy area and a dummy array area. The redundancy area may be tested to screen the bridge defect and a defect of spare memory cells.

During testing, all rows or all columns of the redundancy area may be enabled. As a result, overkill may occur. For example, when two redundancy rows are actually repaired among twelve redundancy rows, the two repaired redundancy rows are test targets. Unfortunately, since only the two redundancy rows cannot be enabled, the twelve redundancy rows must all be tested. For this reason, ten redundancy rows unnecessarily participate in the test of the redundancy area, and thus overkill occurs.

In an attempt to correct overkill, the overall main array area may be tested to enable only a repaired redundancy area. This is because only the repaired redundancy area may be tested, instead of a row or a column of a main array area, when all rows or all columns of the main array area are tested. However, even in this case, a significant number of normal rows or normal columns of the main array area are additionally tested, and thus overkill may still take place. Moreover, the time required for the performing the test increases.

### SUMMARY

In accordance with one or more embodiments, a method for testing a redundancy area of a semiconductor memory device includes receiving a redundancy address to select a redundancy area including spare memory cells to repair normal memory cells; checking the redundancy address based on repair use information to determine whether the redundancy area is an actually repaired area; enabling the redundancy area when the redundancy area is the actually repaired area; and outputting data read from the enabled redundancy area to practically perform redundancy area test.

The repair use information may include blowing information of a master fuse in a fuse box circuit. The master fuse may be an antifuse. The repair use information may include master fuse cutting information. The repair use information may include repair row use information when the redundancy address is a redundancy row address. The repair use information may include repair column use information when the redundancy address is a redundancy column address. The main array area may include the normal memory cells is disabled when the redundancy area is enabled.

An actually unrepaired redundancy row may be disabled in the redundancy area when the redundancy area is enabled. An actually unrepaired redundancy column may be disabled in the redundancy area when the redundancy area is enabled. Outputting output data on the disabled redundancy area as all pass data when data may be output from the enabled redundancy area.

In accordance with one or more other embodiments, a method for testing a redundancy area of a semiconductor memory device includes receiving a redundancy row address to select a row of a redundancy area; checking the redundancy row address based on repair row use information to determine whether the row of the redundancy area is an actually repaired row: enabling the row of the redundancy area when the row of the redundancy area is the actually repaired row; and outputting spare memory cell data read through the enabled row of the redundancy area to practically perform a redundancy area test.

A mode register test redundancy row signal may be generated by a test mode register set signal received from test equipment when the redundancy row address is received. The repair row use information may include fusing information of a master fuse including an antifuse in a fuse box circuit. Among rows of the redundancy area, actually unrepaired redundancy rows may all be disabled when the row of the redundancy area is enabled.

The method may include outputting output data on disabled rows of the redundancy area as all pass data when data is output from the enabled two of the redundancy area.

In accordance with one or more other embodiments, a method for testing a memory includes determining whether a row of a redundancy area of the memory is an actually repaired row, the redundancy area including one or more spare memory cells to repair one or more normal memory cells; enabling the redundancy area when the row is an actually repaired row; disabling actually unrepaired rows of the redundancy area; and controlling data to be read through the enabled row of the redundancy area to perform a redundancy area test.

Determining whether a row of a redundancy area is an actually repaired row may be based on repair row use information. The repair row use information may include fuse information. A main array area including the one or more normal memory cells may be disabled when the redundancy area is enabled. The actually repaired row may include a wordline.

### BRIEF DESCRIPTION OF THE DRAWINGS

Features will become apparent to those of skill in the art by describing in detail exemplary embodiments with reference to the attached drawings in which:

FIG. 1 illustrates an example layout of a memory block;

FIG. 2 illustrates an embodiment of a semiconductor memory device;

FIG. 3 illustrates an embodiment of a control circuit;

FIG. 4 illustrates an embodiment of a test read signal generator;

FIG. 5 illustrates an example for enabling repaired rows in a redundancy area;

FIG. 6 illustrates an example of a test configuration of a test operation;

FIG. 7 illustrates an embodiment of a redundancy area test method;

FIG. 8 illustrates an embodiment of a master fuse;

FIG. 9 illustrates an embodiment of a logic gating circuit;

FIG. 10 illustrates an embodiment applied to a computing device;

FIG. 11 illustrates an embodiment applied to a personal computer;

FIG. 12 illustrates an embodiment applied to a semiconductor memory system;

FIG. 13 illustrates an embodiment applied to a memory module;

FIG. 14 illustrates an embodiment applied to an optical linked semiconductor memory system; and

FIG. 15 illustrates an embodiment applied to a multi-channel semiconductor memory device.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.). Each embodiment described and exemplified herein may include a complementary embodiment.

In accordance with one or more embodiments, a memory cell array of a semiconductor memory device (e.g., a DRAM) may be divided into a plurality of memory banks. Each memory bank may include a plurality of memory blocks.

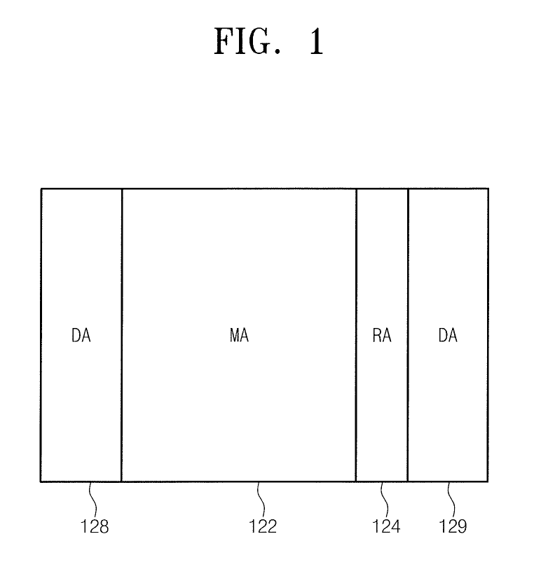

FIG. 1 illustrates an embodiment of a single memory block, which for example, may be included in a memory cell array. Referring to FIG. 1, the memory block includes a main array area 122 including normal memory cells to store data, dummy array regions 128 and 129 including dummy memory cells to ensure normal operation of the normal memory cells, and a redundancy area 124 including spare memory cells for repairing defective normal memory cells. As shown in FIG. 1, the redundancy area 124 is disposed between the main array area 122 and the dummy array area 129. However, the redundancy area 124 may be at different position in another embodiment. Also, in one embodiment, the normal memory cells and spare memory cells may have the same size and the same form, but this is not a necessity. A single DRAM memory cell may include, for example, a single access transistor and a single storage capacitor.

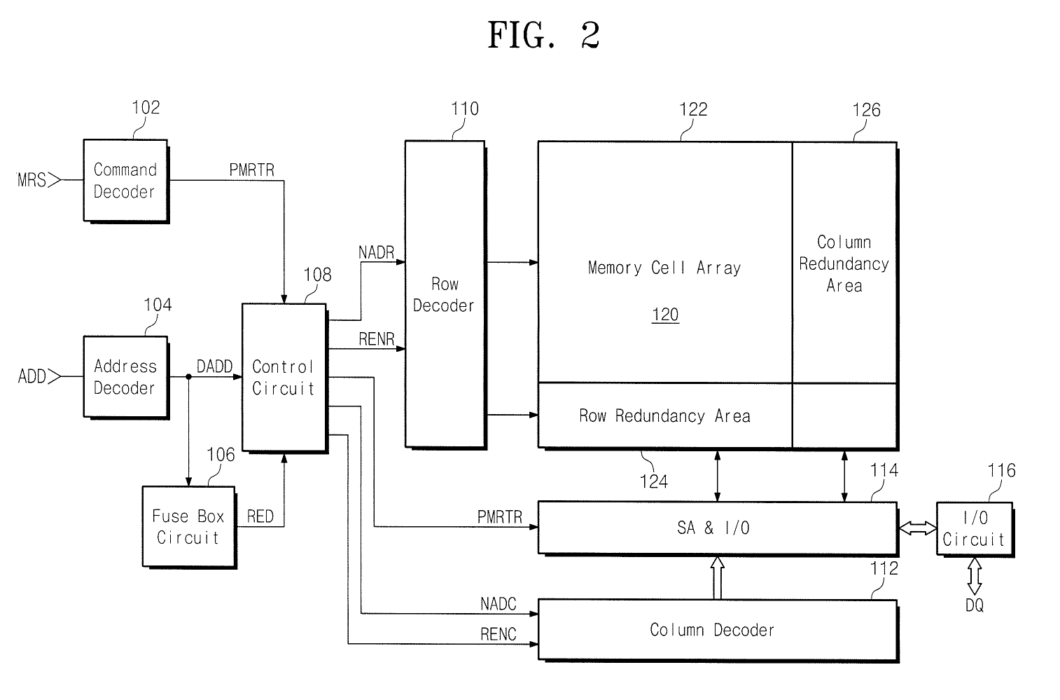

FIG. 2 illustrates an embodiment of a semiconductor memory device which includes a command decoder 102, an address decoder 104, a fuse box circuit 106, a control circuit 108, a row decoder 110, a column decoder 112, a sense amplifier and input/output (I/O) gate (SA & I/O) 114, an I/O circuit 116, and a memory cell array 120. The memory cell array 120 includes a plurality of memory blocks, each having, for example, a structure as illustrated in FIG. 1, connected to a row decoder 110 and a column decoder 112.

The command decoder 102 may generate a redundancy row test signal PMRTR based on a test mode register set TMRS applied during a test of a redundancy area of the semiconductor memory device. The command decoder 102 may generate a column test signal PMRTC based on the test mode register set TMRS. The command decoder 102 decodes various signals (e.g., a row address strobe signal, a column address strobe signal, a write enable signal, and a chip select signal) to generate a command signal. In case of a row-unit repair, a redundancy row test signal PMRTR is generated based on the test mode register set TMRS.

The address decoder 104 decodes an address ADD applied from a test device or a memory controller to generate a decoding address DADD.

The fuse box circuit 106 is a storage circuit including elements (e.g., antifuse) that are programmable by current blowing to store a defect address.

The control circuit 108 checks a redundancy address based on repair use information when receiving a redundancy address to select a redundancy area in which spare memory cells are disposed to repair normal memory cells. For example, the control circuit 108 may determine whether the redundancy area is an actually repaired area.

The row decoder 110 decodes a row address to enable a selected wordline. The row decoder 110 enables a spare wordline based on a repair enable row signal RENR when the redundancy area is an actually repaired area. For example, an enabled spare wordline is an actually repaired wordline instead of a normal wordline.

The column decoder 112 decodes a column address to enable a selected column line. The column decoder 112 enables a spare column line based on a repaired enable column signal RENC when the redundancy area is an actually repaired area. For example, an enabled spare column line is an actually repaired column line instead of a normal column line.

The sense amplifier and I/O gate 114 amplifies and provides data read from a memory cell to an input/output line and applies write data to a selected memory cell.

The I/O circuit 116 outputs read data to an external entity and provides the write data to the sense amplifier and I/O gate 114.

FIG. 2 illustrates a column redundancy area 126, which, for example, may used instead of or in addition to the same row redundancy area 124 in FIG. 1. For example, if a repair is performed in units of rows when defective memory cells exist, a spare wordline may be enabled instead of a defective wordline during a memory access operation. On the other hand, if a repair is performed in units of columns when defective memory cells exist, a spare column line is enabled instead of a defective column line during a memory access operation. The column line may indicate an individual driving line of a column select gate that performs connection with a bitline based on a column select signal.

Spare memory cells and spare row or column lines of the row redundancy area 124 or the column redundancy area 126 may be mainly disposed at the edge portion of a memory block as described with reference to FIG. 1. Accordingly, there may be a bridge defect against a dummy array area 129 in FIG. 1. When repaired spare memory cells include a defect, they may not function as normal memory cells. A test may therefore be performed on the redundancy area using test equipment to screen the bridge defect and a defect of the spare memory cells.

If two redundancy rows are actually repaired among twelve redundancy rows, the two redundancy rows may be test targets. However, in other proposed methods, the twelve redundancy rows are all tested because it is difficult to separately enable only the two redundancy rows. Thus, ten redundancy rows unnecessarily participate in the redundancy area test, thereby resulting in overkill.

A test method for testing the entire main array area to test only a repaired redundancy area may be used to prevent overkill of redundancy rows. This is because, when all rows or all columns in the main array area are tested, only the repaired redundancy area is tested instead of a row or a column of the main array area. According to the test method, a large number of normal rows or normal columns in the main array area additionally participate in the test, to thereby cause overkill and increase the time required for the test.

Therefore, in accordance with one embodiment, in the redundancy area test the control circuit 108 determines whether the redundancy area is an actually repaired area. For example, the control circuit 108 checks a redundancy address based on the repair use information when receiving a redundancy address to select a redundancy area in which spare memory cells are disposed to repair normal memory cells. The repair use information may be master fuse blowing information RPI in the fuse box circuit 106. The master fuse blowing information RPI is a signal provided from the fuse box circuit 106 when a redundancy enable signal RED is applied. When the redundancy address is a row address, a redundancy row address may select all spare wordlines in the redundancy area. The redundancy row address may be provided from a tester. As a result, the control circuit 108 checks the redundancy row address based on the repair use information to determine whether a spare wordline is an actually repaired spare wordline.

When the redundancy area is an actually repaired area, the control circuit 108 applies a repair enable row signal RENR to the row decoder 110 to enable the actually repaired redundancy area. The row decoder 110 enables a repaired spare wordline of the row redundancy area 124 when receiving the repair enable row signal RENR during a redundancy row test operation. As a result, all spare wordlines in the row redundancy area 124 are not enabled, but only an actually repaired spare wordline is enabled during the row redundancy test. Since data is obtained from the enabled redundancy area, a redundancy area test is practically performed.

Thus, in the above case, only the two actually repaired redundancy rows are tested among the twelve redundancy rows. The other ten redundancy rows do not participate in the test. Thus, overkill is prevented and test time is reduced. An enable operation and driving of an actually repaired spare column will be described below.

FIG. 3 illustrates an embodiment of a portion of the control circuit 108 in FIG. 2. The control circuit 108 includes a normal path controller 310, a redundancy path controller 312, and a redundancy enable circuit 314.

The normal controller 310 generates a normal row address disable signal NADR when receiving the redundancy row test signal PMRTR. Thus, all normal wordlines in the memory cell array 120 are disabled. The normal path controller 310 generates a normal column address disable signal NADC when receiving a redundancy column test signal PMRTC. Thus, all normal column lines in the memory cell array 120 are disabled.

The redundancy path controller 312 generates a redundancy row address enable signal when receiving the redundancy row test signal PMRTR. The redundancy row address enable signal is applied to a repair redundancy enable circuit 314 without being applied to the row decoder 110. The redundancy path controller 312 generates a redundancy column address enable signal when receiving the redundancy column test signal PMRTC. The redundancy column address enable signal is applied to a repair redundancy enable circuit 314 without being applied to the column decoder 112.

The repair redundancy enable circuit 314 gates the redundancy row address RADD selecting a row of a redundancy area with the repair use information to generate an AND response when the row address enable signal is enabled. For example, when the master fuse blowing information RPI in the fuse box circuit 106 indicates an actually repaired spare wordline, a redundancy row address RADD is made valid. As a result, when a defective normal wordline is repaired by a spare wordline, a corresponding master fuse is blown during a fuse program operation. Thus, when information indicating whether the master fuse is blown is used in the test, only the actually spare wordline may be enabled during the redundancy area test. The master fuse may include, for example, an antifuse that is ruptured by high current.

The AND response of the repair redundancy enable circuit 314 becomes an enable row signal RENR. The repair enable row signal RENR is applied to the row decoder 110 to enable only the actually repaired spare wordline, among the spare wordlines in the row redundancy area 124, during the row redundancy test.

The repair redundancy enable circuit 314 gates a redundancy column address CADD selecting a column of a redundancy area with the repair use information to generate an AND response when the column address enable signal is enabled. For example, when the master fuse blowing information RPI in the fuse box circuit 106 indicates an actually repaired spare column line, a redundancy column address CADD is made valid. As a result, when a defect normal column line is repaired by a spare column line, a corresponding master fuse is blown during a fuse program operation. Thus, when information on whether the master fuse is blown is used in the test, only the actually spare column line may be enabled during the redundancy area test.

The AND response of the repair redundancy enable circuit 314 becomes a repair enable column signal RENC. The repair enable column signal RENC is applied to the column decoder 112 to enable only the actually repaired spare column line among the spare column lines in the column redundancy area 126 during a column redundancy test.

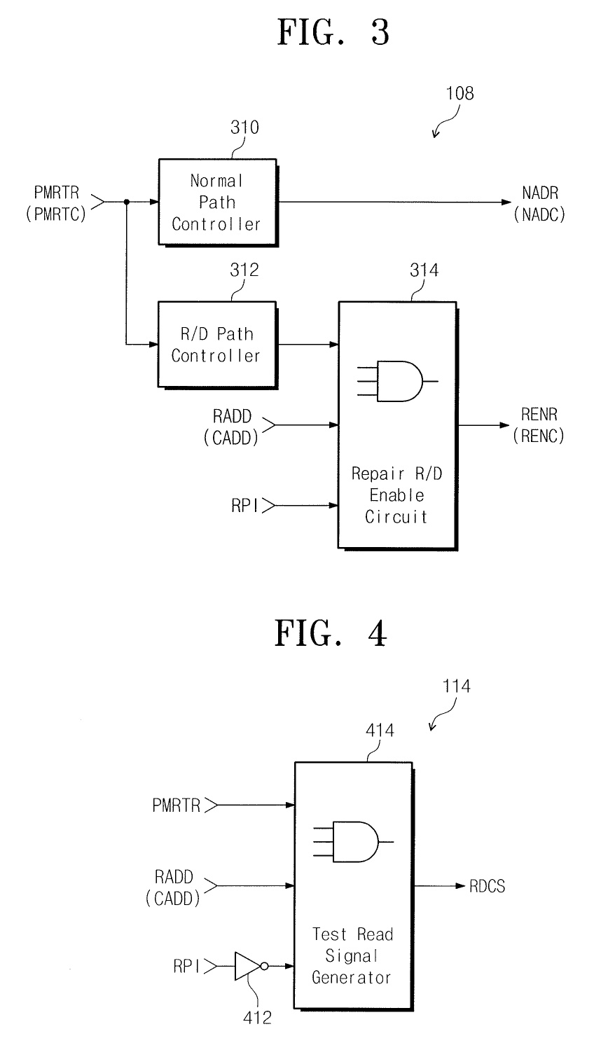

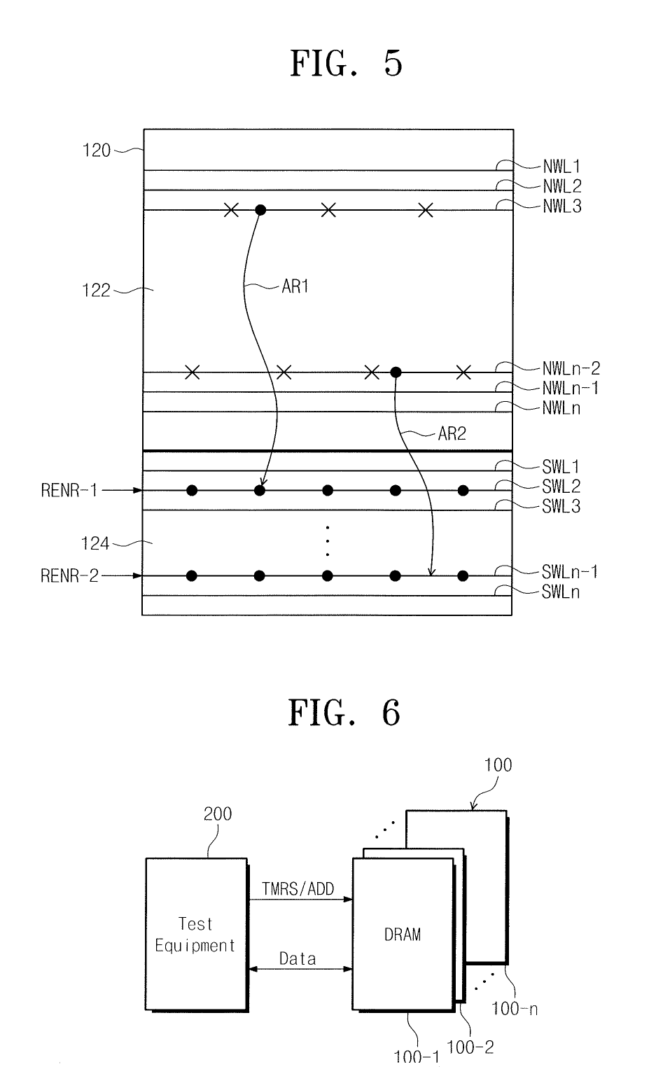

FIG. 4 illustrates an embodiment of a test read signal generator 414 that may be applied to the sense amplifier and input/output gate 114 in FIG. 2. As illustrated, the test read signal generator 414 generates a test read signal RDCS to unconditionally pass read data output from spare wordlines or spare column lines that are not enabled during a read operation for a redundancy test. For example, the test read signal RDCS is a read “don't care” signal.

The test read signal generator 414 generates an AND response by gating the redundancy row test signal PMRTR, the redundancy row address RADD, and the master fuse blowing information RPI inverted through the inverter 412. The AND response becomes the test read signal RDCS indicating a read “don't care” signal.

According to the above, the test read signal generator 414 may be applied to the sense amplifier and I/O gate 114 in FIG. 2. In another embodiment, the test read signal generator 414 may be mounted in the control circuit 108 or the I/O circuit 116.

FIG. 5 illustrates an embodiment for enabling repaired rows in a redundancy area according to the operation of FIG. 2. Referring to FIG. 5, a memory cell array 120 may include a main array area 122 in which normal memory cells are disposed and a redundancy area 124 in which spare memory cells are disposed to repair a defect of the normal memory cells. Dummy array areas 128 and 129 in FIG. 1 are not shown in FIG. 5 for improved understanding, and spare wordlines SWL1 to SWLn in a row redundancy area 124 are shown to explain a row redundancy test.

For illustrative purposes, it may be assumed that, among a plurality of normal wordlines in a main array area 122, two normal wordlines NWL3 and NWLn-2 are repaired by two spare wordlines SWL2 and SWLn-1, as indicated by arrows AR1 and AR2. Under this assumption, only the two spare wordlines SWL2 and SWLn-1 are enabled by repair enable row signals RENR-1 and RENR-2 during a redundancy area test. For example, only the two spare wordlines SWL2 and SWLn-1 are enabled without enabling all spare wordlines SWL1 to SWLn in the row redundancy area 124. Thus, overkill is prevented and time for the test is reduced.

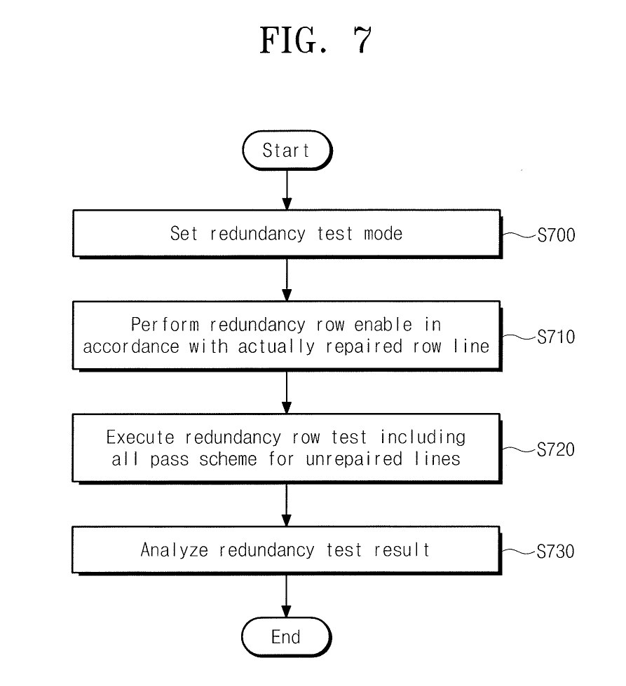

FIG. 6 illustrates an embodiment of a test configuration of a test operation. Referring to FIG. 6, the semiconductor memory device in FIG. 2 may be a single DRAM 100. A plurality of DRAMs 100-1 to 100-n may be connected to a single test equipment 200. The test equipment 200 may apply not only a command but also a test mode register set TMRS and an address ADD to the DRAM 100 during a redundancy area test. In addition, the test equipment 200 may apply test data DATA to the DRAM 100 and receive a test result signal from the DRAM 100.

The single DRAM 100 may include two or more dies to form a single multi-channel semiconductor device. As a result, a single die may correspond to a single chip. Thus, of two chips, the first chip may be a first die manufactured on a wafer and the second chip may be a second die manufactured on the same wafer as the wafer or a different wafer than the wafer. In accordance with at least one embodiment, a die may correspond to an individual chip manufactured on a wafer. Before a plurality of dies are divided on a wafer, they dies may be manufactured at one time through various semiconductor manufacturing processes to form individual chips. An oxidation process, a photolithography process, a thin film formation process, an etch process, or a chemical mechanical polishing (CMP) process may be, for example, one of the various semiconductor manufacturing processes.

Although a DRAM is connected as a memory in FIG. 6, an MRAM may be mounted instead of the MRAM in another embodiment.

Volatile memory devices such as SRAM and DRAM lose stored data when their power supplies are interrupted, while nonvolatile memory devices such as MRAM retain stored data even when their power supplies are interrupted. Accordingly, nonvolatile memory devices are often used to store data when data should not be lost during, for example, a power failure or power-off operation.

When a spin transfer torque magneto resistive random access memory (STT-MRAM) constitutes a memory module, advantages of an MRAM may be added to the advantages of a DRAM. An STT-MRAM cell may include, for example, a magnetic tunnel junction (MTJ) element and a select transistor. The MTJ element may basically include a pinned layer, a free layer, and a tunnel layer disposed therebetween. A magnetization direction of the pinned layer is fixed, and a magnetization of the free layer is identical or reverse to that of the pinned layer according to various conditions.

In FIG. 6, the DRAM 100 may have a configuration where two or more dies 3550 and 3551 are in a single package. For example, the DRAM 100 may be packaged by one of PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), or Wafer-Level Processed Stack Package (WSP).

FIG. 7 illustrates an embodiment of a redundancy area test method. Referring to FIG. 7, the control circuit 108 sets a redundancy test mode for testing a redundancy area when the command decoder 102 receives a test mode register set TMRS (S700).

Redundancy row enable is performed in accordance with an actually repaired wordline (S710). To achieve this, when receiving a redundancy row address to select a row of a redundancy area, the control circuit 108 checks the redundancy row address based on repair row use information to determine whether the row of the redundancy area is an actually repaired row. As a result, the row of the redundancy area is enabled only when a spare wordline of the redundancy area is an actually repaired spare wordline. Since read spare memory cell data is actually output through the enabled row of the redundancy area, a redundancy area test is actually executed.

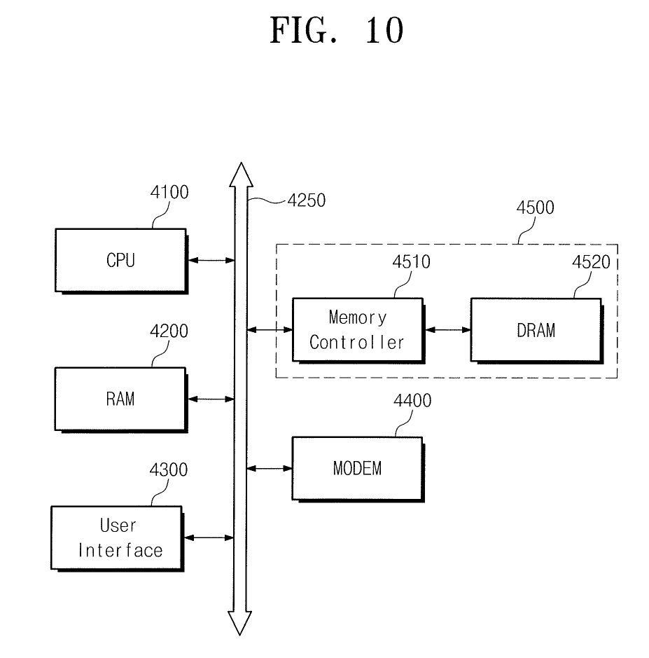

A redundancy row test is executed by applying an all pass scheme to unrepaired spare wordlines (S720). An example of the all pass scheme will be described with reference to FIG. 9.

Test-completed data is provided to the test equipment 200 to analyze a redundancy test result (S730).

In the method of FIG. 7, when a redundancy row address is received to select a row of a redundancy area, the redundancy row address is checked based on repair row use information to determine whether the row of the redundancy area is an actually repaired row. When the row of the redundancy area is the actually repaired row, the row of the redundancy area is enabled and read spare memory cell data is output through the enabled row of the redundancy area.

When a redundancy row address is received, a test redundancy row signal is generated from the command decoder 102 in FIG. 2 by a test mode register set signal received from a test device. On the other hand, when a redundancy column address is received to select a column of the redundancy area, the redundancy column address may be checked based on repair column use information to determine whether the column of the redundancy area is an actually repaired column.

As a result, when the column of the redundancy area is the actually repaired column, the column of the redundancy area is enabled and read spare memory cell data is output through the enabled column of the redundancy area.

The repair column use information may be rupturing information of a master use to store information on the redundancy use in a fuse box circuit. Similarly, when the column of the redundancy area is enabled, actually unrepaired redundancy columns may be all disabled among columns of the redundancy area.

The test method may further include an operation of outputting output data on disabled columns of the redundancy area as all pass data when data is output from the enabled column of the redundancy area.

According to the test method of FIG. 7, since only an actually repaired redundancy area of a redundancy area is tested, the time for the test is reduced. In addition, the method may prevent overkill when the entire redundancy area is tested or the entire main array area is tested to enable only a repaired redundancy area.

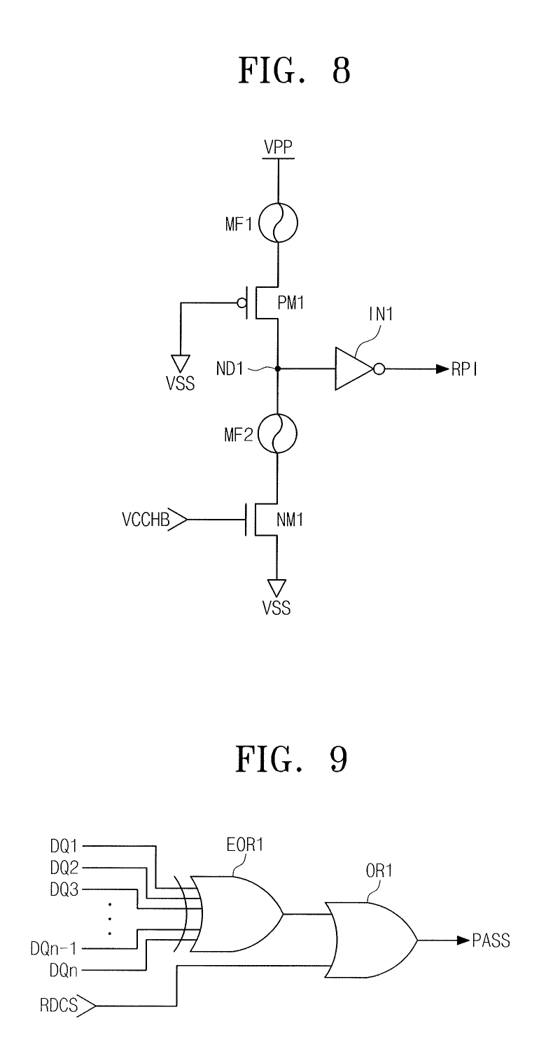

FIG. 8 illustrates an embodiment of a master fuse to generate repair use information for FIG. 3. The master fuse circuit includes first and second master fuses MF1 and MF2, a PMOS transistor PM1, an NMOS transistor NM1, and an inverter IN1.

When a certain spare wordline is not repaired, the first master fuse MF1 is not blown but the second master fuse MF2 is blown. Since a high power supply voltage VPP appears through the first master fuse MF1 and a channel of the PMOS transistor PM1 when the first master fuse MF1 is not blown but the second master fuse MF2 is blown, master fuse blowing information RPI is obtained as logic low (logic “0”) by an inverter IN1 to invert a logic level of a node ND1.

When a certain spare wordline is repaired, the first master fuse MF1 is blown but the second master fuse MF2 is not blown. When the master fuse MF1 is blown but the second master fuse MF2 is not blown, a high power supply voltage VPP does not appear at the node ND1 through the first master fuse MF1 and a channel of the PMOS transistor PM1. When a power apply signal VCCHB is high, the NMOS transistor NM1 is turned on to set the potential of the node ND1 to a ground level. Thus, the master fuse blowing information RPI is obtained as logic high (logic “1”) by the inverter IN1 to invert the logic level of the node ND1.

As set forth above, the master fuse blowing information RPI may be monitored to check whether a spare wordline is an actually repaired spare wordline.

The master fuse blowing information RPI of the master fuse circuit may be connected to a plurality of address fuse boxes. Each of the address fuse boxes may precode a given number of external addresses to receive a predetermined number of obtained signals. Each of the address fuse boxes stores a repair address by cutting unit fuses. Each of the address fuse box determines whether a stored (programmed) repair address and an input address are identical to each other. As a result, a spare memory cell is accessed when the repair address and the input address are identical to each other.

FIG. 9 illustrates an embodiment of a logic gating circuit that may be applied to an input/output circuit in FIG. 2. The logic gating circuit includes an exclusive OR gate EOR1 and an OR gate OR1.

The exclusive OR gate EOR1 outputs a logic low when a plurality of data DQ1 to DQn have the same logic level and outputs a logic high when one of the data DQ1 to DQn have a different level. However, when a test read signal RDCS is applied as a logic high, an output of the OR gate OR1 becomes logic high irrespective of an output logic level of the exclusive OR gate EOR1. For example, the output of the exclusive OR gate EOR1 corresponds to “don't care.” Likewise, an all pass signal PASS is output as logic high when a test read signal RDCS is generated.

As a result, read data output from non-enabled spare wordlines or non-enabled spare column lines is unconditionally passed during a read operation for a redundancy test. Thus, although unrepaired spare wordlines are not enabled, the test equipment 200 may be informed that unrepaired spare wordlines do not fail.

FIG. 10 illustrates an embodiment applied to a computing device which includes a memory system 4500 including a DRAM 4520 and a memory controller 4510. The computing device may include an information processing device or a computer. The computing device may further include a modem 4400, a central processing unit (CPU) 4100, a RAM 4200, and a user interface 4300 that are electrically connected to a system bus 4250. Data processed by the CPU 4100 or externally input data may be stored in the memory system 4500. When the DRAM 4520 is a DDR4 DRAM, the DRAM 4520 may be manufactured with at least two dies in a mono package.

The computing device may be applied to a solid state disk (SSD), a camera image sensor, and other application chipsets. In some embodiments, the memory system 4500 may be configured with an SSD. In this case, the computing device may stably and reliably store large-capacity data in the memory system 4500.

In the memory system 4500, the memory controller 4510 may apply a command, an address, data or other control signals to the DRAM 4520.

The CPU 4100 functions as a host and controls the overall operation of the computing device. A host interface between the CPU 4100 and the memory controller 4150 may include various protocols for data exchange between a host and the memory controller 4500. In exemplary embodiments, memory controller 4510 may communicate with a host or an external device through one of various interface protocols such as USB (Universal Serial Bus) protocol, MMC (Multimedia Card) protocol, PCI (Peripheral Component Interconnection) protocol, PCI-E (PCI-Express) protocol, ATA (Advanced Technology Attachment) protocol, SATA (Serial ATA) protocol, ESDI (Enhanced Small Disk Interface) protocol, and IDE (Integrated Drive Electronics) protocol.

The computing device in FIG. 10 may be applied, for example, as one of a computer, an Ultra Mobile PC (UMPC), a digital picture player, a digital video recorder, a digital video player, a storage constituting a data center, a device capable of transmitting/receiving data in an wireless environment and various electronic devices constituting a home network, one of various electronic devices constituting a computer network, one of various electronic devices constituting a telematics network, a radio-frequency identification (RFID) device, or one of various constituents constituting a computing system.

Since only an actually repaired redundancy area of a redundancy area is tested during a test before the DRAM 4520 in FIG. 10 is shipped, the time for the test is reduced. In addition, overkill is prevented which occurs when the entire redundancy area is tested or the entire main array area is tested to enable only a repaired redundancy area. Thus, the cost for implementing a computing device may be reduced and operation performance may be enhanced.

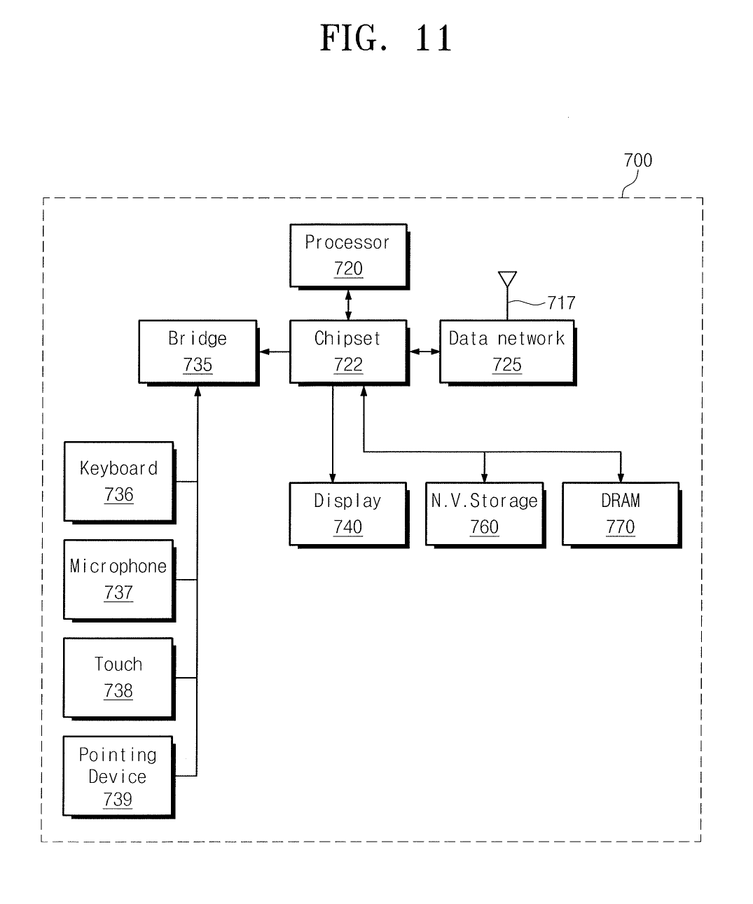

FIG. 11 illustrates an embodiment applied to a personal computer 700, which includes a processor 720, a chipset 722, a data network 725, a bridge 735, a display 740, a nonvolatile storage 760, a DRAM 770, a keyboard 736, a microphone 737, a touch unit 738, and a pointing device 739. The DRAM 770 may have the same configuration as in FIG. 2. Therefore, the cost for implementing the personal computer 700 may be reduced and operation performance may be enhanced.

The chipset 722 may apply a command, an address, data or other control signals to the DRAM 770.

The processor 720 functions as a host and controls the overall operation of the personal computer 700. A host interface between the processor 720 and the chipset 722 includes various protocols for performing data communication.

The nonvolatile storage 760 may be implemented with, for example, an electrically erasable programmable read-only memory (EEPROM), a flash memory, a magnetic RAM (MRAM), a spin-transfer torque MRAM (STT-MRAM), CBRAM (a conductive bridging RAM (CBRAM), a ferroelectric RAM (FRAM), a phase change RAM (PRAM) called an ovonic unified memory (OUM), a resistive RAM (RRAM or ReRAM), nanotube RRAM, a nanotube RRAM, a polymer RAM (PoRAM), a nano floating gate memory (NFGM), holographic memory, a molecular electronics memory device or an insulator resistance change memory.

The personal computer 700 in FIG. 11 may be provided as one of various elements constituting an electronic device such as a computer, an ultra-mobile PC (UMPC), a workstation, a net-book, a personal digital assistant (PDA), a portable computer, a web tablet, a wireless phone, a mobile phone, a smart phone, an e-book, a portable multimedia player (PMP), a portable game device, a navigation device, a black box, a digital camera, a digital multimedia broadcasting (DMB) player, a three-dimensional television, a smart television, a digital audio recorder, a digital audio player, a digital picture recorder, a digital picture player, a digital video recorder, and a digital video player, a device capable of transmitting/receiving information in wireless environment, one of various electronic devices constituting a home network, an RFID device or one of various elements constituting a computing system.

Since only an actually repaired redundancy area of a redundancy area is tested during a test before the DRAM 770 in FIG. 11 is shipped, the time for the test is reduced. In addition, the processor 720 and the chipset 722 may function as a test equipment.

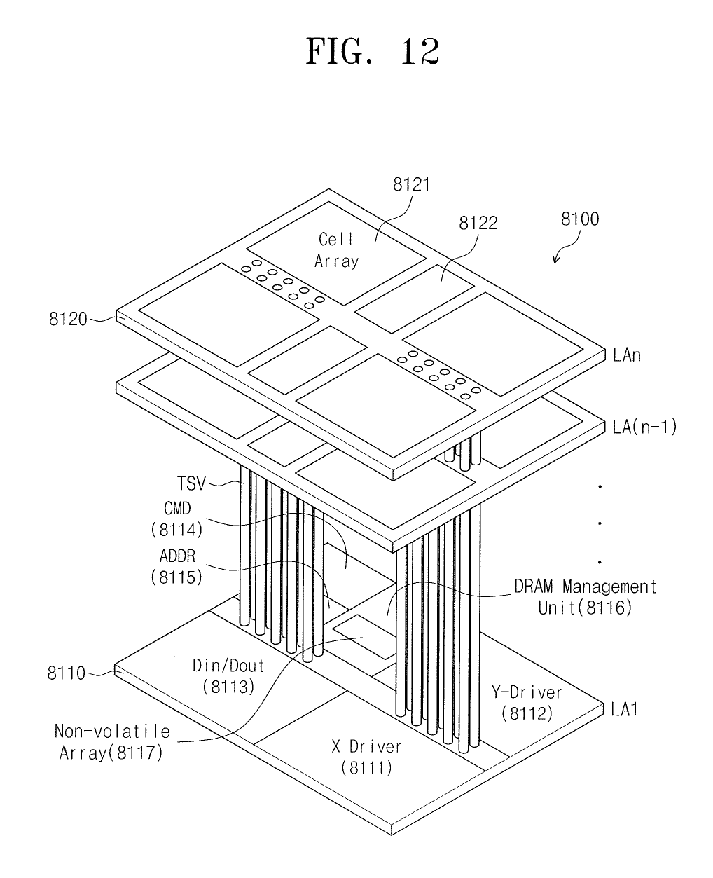

FIG. 12 illustrates an embodiment applied to a semiconductor memory system 8100, which is implemented by stacking a plurality of semiconductor layers. As illustrated in FIG. 12, the semiconductor memory system 8100 includes a plurality of semiconductor layers LA1 to LAn. Each of the semiconductor layers LA1 to LAn may be a memory chip including a DRAM cell. In another embodiment, some of the semiconductor layers LA1 to LAn may be master chips interfacing with an external controller and other layers may be slave chips to store data. For illustrative purposes only, in FIG. 12, it is assumed that a lowermost semiconductor layer LA1 is a master chip and the other semiconductor layers LA2 to LAn are slave chips.

The semiconductor layers LA1 to LAn transmit and receive a signal to and from each other through a through-silicon via (TSV), and the master chip LA1 communicates with an external memory controller through an external conductive element. The configuration and operation of the semiconductor memory device 8100 will be described below by focusing on the first semiconductor layer 8110 as a master chip and an n^{th} semiconductor layer 8120 as a slave chip.

The first semiconductor layer 8110 includes various types of circuits to drive a cell array 8121 included in slave chips. For example, the first semiconductor layer 8110 may include a row driver (X-Driver) 8111 to drive a wordline of a cell array 8121, a column driver (Y-Driver) 8112 to drive a bitline, an input/output unit 8113 to control data input/output, a command decoder 8114 to decode an external command CMD, and an address buffer 8115 to receive and buffer an external address.

The first semiconductor layer 8110 may further include a DRAM management unit 8116 to manage a memory operation of a slave chip. The DRAM management unit 8116 may include a nonvolatile array 8117 to weak page addresses or memory characteristics of areas of the cell array 8121 or information associated with a sub-block. When receiving a row command accompanied by a specific one (e.g., row address) of commands received from an external controller, the DRAM management unit 8116 may compare the row address with the information stored in the nonvolatile array 8117 and provide a flag FLAG or information bits Info Bits depending on a result of the comparison to the external controller.

The n^{h} semiconductor layer 8120 may include a cell array 8121 and a peripheral circuit area 8122 in which other peripheral circuits to drive the cell array 8121, e.g., a row/column selector to select a row and a column and a bitline sense amplifier are disposed. Since only an actually repaired redundancy area of a redundancy area is tested during a test before the DRAM in FIG. 12 is shipped, the time for the test is reduced.

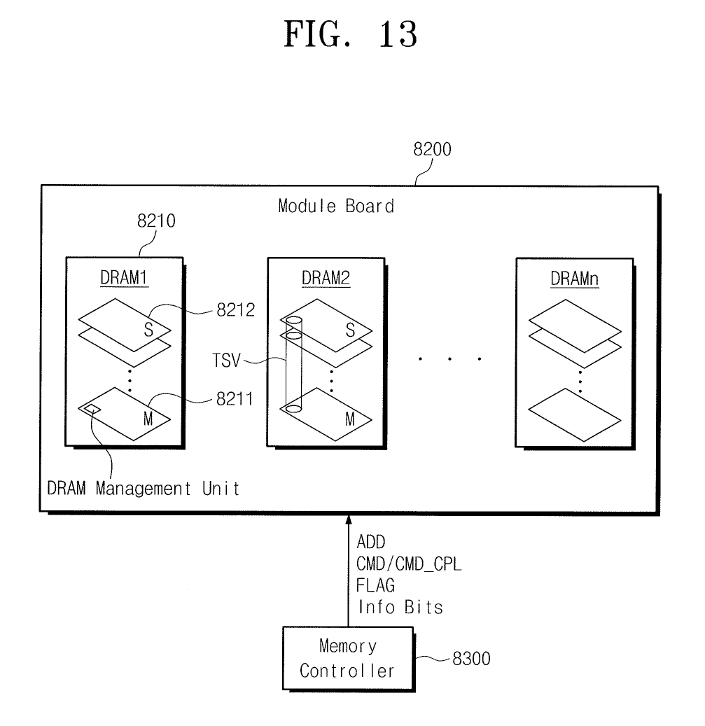

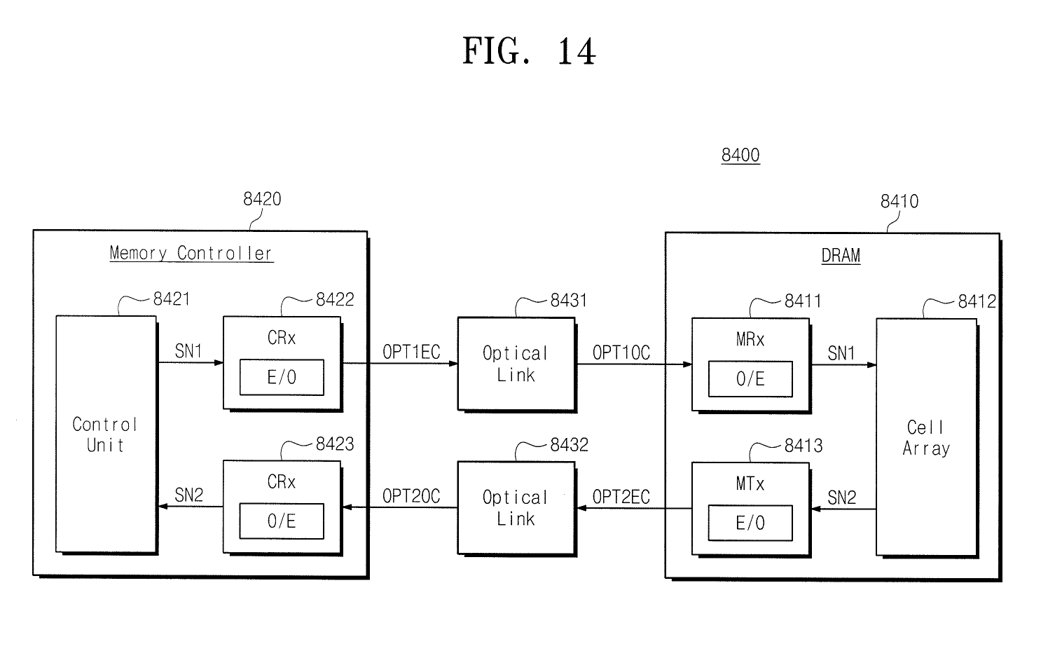

FIG. 13 illustrates an embodiment applied to a memory module 8200. For convenience of description, not only the memory module 8200 but also a memory controller 8300 is shown in FIG. 13.

As illustrated in FIG. 13, the memory module 8200 includes one or more semiconductor memory devices 8210 mounted on a module board. The semiconductor memory device 8210 may be implemented with a DRAM chip. Each of the semiconductor memory devices 8210 includes a plurality of semiconductor layers. The semiconductor layers include one or more master chips 8211 and one or more slave chips 8212.

Signal transmission between the semiconductor layers may be performed through a through-silicon via (TSV). The memory module 8200 communicates with the memory controller 8300 to transmit and receive command CMD/CMD_CPL, address ADD, flag FLAG, and information bits Info Bits between the memory module 8200 and the memory controller 8300.

The semiconductor memory device 8210 in FIG. 13 may have the same configuration as in FIG. 2. Thus, only an actually repaired redundancy area of a redundancy area is tested during a test before the DRAM 770 in FIG. 11 is shipped. As a result, the time for the test is reduced, which decreases the cost for implementing a memory module and enhance operation performance.

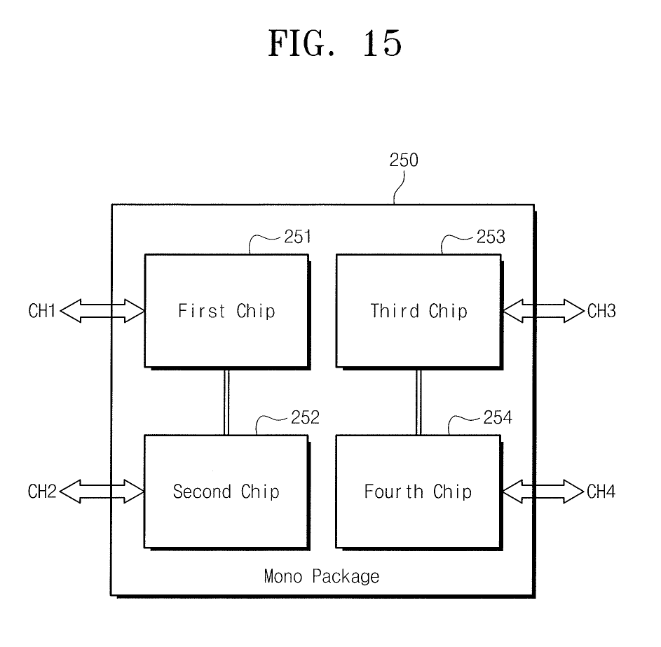

FIG. 14 illustrates an embodiment applied to an optical linked semiconductor memory system 8400. The memory system 8400 includes optical connection devices 8431 and 8432, a memory controller 8420, and a semiconductor memory device 8410. The semiconductor memory device 8410 is, for example, a DRAM.

The optical connection devices 8431 and 8432 interconnect the memory controller 8420 and the semiconductor memory device 8410. The memory controller 8420 includes a control unit 8421, a first transmitter 8422, and a first receiver 8423. The control unit 8421 transmits a first electrical signal SN1 to the first transmitter 8422. The first electrical signal SN1 may include a command, a clock signal, an address, and data transmitted to the semiconductor memory device 8410. The first transmitter 8422 includes an optical modulator E/O. The optical modulator E/O converts the first electrical signal SN1 into a first optical transmission signal OTP1EC and transmits the first optical transmission signal OTP1EC to the optical connection device 8431. The first optical transmission signal OTP1EC is transmitted to serial communication through the optical connection device 8431. The first receiver 8423 includes an optical demodulator O/E. The optical demodulator O/E converts a second optical reception signal OPT2OC received from the optical connection device 8430 into a second electrical signal SN2 and transmits the second electrical signal SN2 to the control unit 8420.

The semiconductor memory device 8410 includes a second receiver 8411, a cell array 8412, and a second transmitter 8413. The second receiver 8411 includes an optical demodulator O/E. The optical demodulator O/E converts the first optical reception signal OPT1OC from the optical connection device 8430 into the first electrical signal SN1 and transmits the first electrical signal SN1 to a cell array 8412.

In the cell array 8412, write data is written into a memory cell or data read from the cell array 8412 is transmitted to the second transmitter 8413 as the second electrical signal SN2 based on the first electrical signal SN1. The second electrical signal SN2 may include a clock signal and read data transmitted to the memory controller 8420. The second transmitter 8413 includes an optical modulator E/O. The optical modulator E/O converts the second electrical signal SN2 into the second optical transmission signal OPT2EC and transmits the second optical transmission signal OPT2EC to the optical connection device 8432. The second optical transmission signal OTP2EC is transmitted to serial communication through the optical connection device 8432.

The DRAM 8410 in FIG. 14 may have the same configuration as in FIG. 2, and the memory controller 8420 may perform optical interfacing between a test equipment and the DRAM 8410. As a result, only an actually repaired redundancy area of a redundancy area is tested. Thus, the time for the test is reduced.

FIG. 15 illustrates an embodiment applied to a multi-channel semiconductor memory device 250 which includes four chips 251, 252, 253, and 254 with four dies. In FIG. 15, the multi-channel semiconductor memory device 250 may include a DRAM as in FIG. 2.

A first interconnection is formed between the first chip 251 and the second chip 252, and a second interconnection is formed between the third chip 253 and the fourth chip 254. In a mono package, the multi-channel semiconductor device 250 includes fourth channels.

Although the first chip 251 and the second chip 252 include two dies, they may perform the same data input/output operation as a two-channel semiconductor memory device manufactured from a mono die.

Although the third chip 253 and the fourth chip 254 include two dies, they may perform the same data input/output operation as a two-channel semiconductor memory device manufactured from a mono die.

As described above, since only an actually repaired redundancy area of a redundancy area is tested, the time for the test is reduced. In addition, overkill is prevented which occurs when the entire redundancy area is tested or the entire main array area is tested to enable only a repaired redundancy area.

The methods, processes, and/or operations described herein may be performed by code or instructions to be executed by a computer, processor, controller (e.g., control circuit 108), or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods described herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments described herein.

In one embodiment, the control circuits and other processing features of the embodiments disclosed herein may be implemented in logic which, for example, may include hardware, software, or both. When implemented at least partially in hardware, the BMS may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the control circuits and other processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

For example, in accordance with one embodiment, an apparatus includes an interface coupled to a memory device; and a controller to coupled to the interface to generate one or more control signals to: select a redundancy area based on a redundancy address, the redundancy area including spare memory cells to repair normal memory cells in the memory device; check the redundancy address based on repair use information to determine whether the redundancy area is an actually repaired area; enable the redundancy area when the redundancy area is the actually repaired area; and control output of data read from the enabled redundancy area to practically perform a redundancy area test.

The interface may take various forms. For example, when the control circuit (e.g., control circuit 108) is embodied within an integrated circuit chip, the interface may be one or more output terminals, leads, wires, ports, signal lines, or other type of interface without or coupled to the control circuit. In another case, the interface may be one or more signal lines within the control circuit itself.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the invention as set forth in the following claims.

What is claimed is:

1. A method for testing a redundancy area of a semiconductor memory device, the method comprising:
receiving a redundancy address to select a redundancy area including spare memory cells to repair normal memory cells;
checking the redundancy address based on repair use information to determine whether the redundancy area is an actually repaired area;
enabling the redundancy area when the redundancy area is the actually repaired area; and
outputting data read from the enabled redundancy area to practically perform a redundancy area test.

2. The method as claimed in claim 1, wherein the repair use information includes blowing information of a master fuse in a fuse box circuit.

3. The method as claimed in claim 2, wherein the master fuse is an antifuse.

4. The method as claimed in claim 1, wherein the repair use information includes master fuse cutting information.

5. The method as claimed in claim 1, wherein the repair use information includes repair row use information when the redundancy address is a redundancy row address.

6. The method as claimed in claim 1, wherein the repair use information includes repair column use information when the redundancy address is a redundancy column address.

7. The method as claimed in claim 1, wherein a main array area including the normal memory cells is disabled when the redundancy area is enabled.

8. The method as claimed in claim 1, wherein an actually unrepaired redundancy row is disabled in the redundancy area when the redundancy area is enabled.

9. The method as claimed in claim 1, wherein an actually unrepaired redundancy column is disabled in the redundancy area when the redundancy area is enabled.

10. The method as claimed in claim 1, further comprising:
outputting output data on the disabled redundancy area as all pass data when data is output from the enabled redundancy area.

11. A method for testing a redundancy area of a semiconductor memory device, the method comprising:
receiving a redundancy row address to select a row of a redundancy area;
checking the redundancy row address based on repair row use information to determine whether the row of the redundancy area is an actually repaired row;
enabling the row of the redundancy area when the row of the redundancy area is the actually repaired row; and
outputting spare memory cell data read through the enabled row of the redundancy area to practically perform a redundancy area test.

12. The method as claimed in claim 11, wherein a mode register test redundancy row signal is generated by a test mode register set signal received from a test equipment when the redundancy row address is received.

13. The method as claimed in claim 11, wherein the repair row use information includes fusing information of a master fuse including an antifuse in a fuse box circuit.

14. The method as claimed in claim 11, wherein among rows of the redundancy area, actually unrepaired redundancy rows are all disabled when the row of the redundancy area is enabled.

15. The method as claimed in claim 11, further comprising:
outputting output data on disabled rows of the redundancy area as all pass data when data is output from the enabled row of the redundancy area.

16. A method for testing a memory, the method comprising:
determining whether a row of a redundancy area of the memory is an actually repaired row, the redundancy area including one or more spare memory cells to repair one or more normal memory cells;
enabling the redundancy area when the row is an actually repaired row;
disabling actually unrepaired rows of the redundancy area; and
controlling data to be read through the enabled row of the redundancy area to perform a redundancy area test.

17. The method as claimed in claim 16, wherein determining whether a row of a redundancy area is an actually repaired row based on repair row use information.

18. The method as claimed in claim 17, wherein the repair row use information includes fuse information.

19. The method as claimed in claim 16, wherein a main array area including the one or more normal memory cells is disabled when the redundancy area is enabled.

20. The method as claimed in claim 16, wherein the actually repaired row includes a wordline.
